(19) United States
(12) Patent Application Publication
(10) Pub. No.: US 2026/0123246 A1
(43) Pub. Date: Apr. 30, 2026

(54) DISPLAY PANEL AND DISPLAY APPARATUS

(71) Applicant: WUHAN CHINA STAR OPTOELECTRONICS SEMICONDUCTOR DISPLAY TECHNOLOGY CO., LTD., Wuhan (CN)

(72) Inventor: Hai LIN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/067,380

(22) Filed: Feb. 28, 2025

Related U.S. Application Data
(63) Continuation of application No. PCT/CN2024/130276, filed on Nov. 6, 2024.

(30) Foreign Application Priority Data
Oct. 30, 2024 (CN) 202411531001.9

(51) Int. Cl. H10K 59/80

(52) U.S. Cl. CPC H10K 59/874

(57) ABSTRACT

A display panel includes a substrate, a planarization layer disposed on the substrate, a plurality of first electrodes arranged in an array, and a plurality of light-emitting function layers respectively covering the first electrodes. The planarization layer includes a planarization body and a plurality of protrusions arranged in a first direction on the planarization body, and each of the protrusions extends along a second direction. In the first direction, each first electrode is located between two adjacent protrusions and spaced from at least one of the two adjacent protrusions by a gap. The gap is filled with a part of one of the light-emitting function layers covering the first electrode.

### CROSS-REFERENCE TO RELATED APPLICATIONS

This application is a continuation of International Application No. PCT/CN2024/130276, filed on Nov. 6, 2024, which claims priority to Chinese Patent Application No. 202411531001.9, filed on Oct. 30, 2024. The disclosures of the abovementioned applications are incorporated herein by reference in their entireties.

### TECHNICAL FIELD

The present application relates to display technologies, and in particular to a display panel and a display apparatus.

### BACKGROUND

Organic light-emitting diode (OLED) display panels have properties such as self-luminescence, fast response, wide viewing angles, and high brightness and are thus widely used in display apparatuses.

In the related art, an OLED display panel may include an array substrate and light-emitting devices. Each light-emitting device may include a first electrode, a light-emitting function layer, and a second electrode that are stacked on the array substrate. However, ink used to form the light-emitting function layer is prone to significant climb, thereby affecting the display effect of the OLED display panel.

### SUMMARY

According to some embodiments of the present application, a display panel includes: a substrate; a planarization layer disposed on the substrate, the planarization layer including a planarization body and a plurality of protrusions arranged side by side in a first direction on a side of the planarization body away from the substrate, each of the protrusions extending along a second direction; a plurality of first electrodes arranged in an array on the planarization body, where in the first direction each of the first electrodes is located between two adjacent ones of the protrusions and spaced from at least one of the two adjacent ones of the protrusions by a gap; and a plurality of light-emitting function layers respectively covering the first electrodes. The gap is filled with a part of one of the light-emitting function layers covering the each of the first electrodes.

According to some embodiments of the present application, a display apparatus includes the above display panel.

### BRIEF DESCRIPTION OF THE DRAWINGS

FIG. 1 is a schematic sectional view of a structure of an OLED display panel in the related art.

FIG. 2 is a schematic diagram of a structure of a display panel, without any light-emitting function layer disposed, according to some embodiments of the present application.

FIG. 3 is a schematic sectional view of an example structure of the display panel, with light-emitting function layers disposed, along the A-A′ line in FIG. 2.

FIG. 4 is a schematic sectional view of another example structure of the display panel, with light-emitting function layers disposed, along the A-A′ line in FIG. 2.

FIG. 5 is a schematic sectional view of a structure of the display panel, with light-emitting function layers disposed, along the B-B′ line in FIG. 2.

FIG. 6 is a schematic sectional view of another structure of a display panel according to some embodiments of the present application.

FIG. 7 is a schematic diagram of yet another structure of a display panel, without any light-emitting function layer disposed, according to some embodiments of the present application.

FIG. 8 is a schematic sectional view of a structure of the display panel, with light-emitting function layers disposed, along the C-C′ line in FIG. 7.

FIG. 9 is a schematic diagram of a structure of a display apparatus according to some embodiments of the present application.

### DETAILED DESCRIPTION

Some embodiments of the present application will be described in detail below with reference to the accompanying drawings. The embodiments are described for illustrative purposes only and are not intended to limit the present application.

Herein, terms such as “first”, “second” and similar words do not indicate any order, quantity, or importance, but are used to distinguish different technical features. Terms such as “multiple”, “a plurality of” and the like indicate two or more unless otherwise specifically limited.

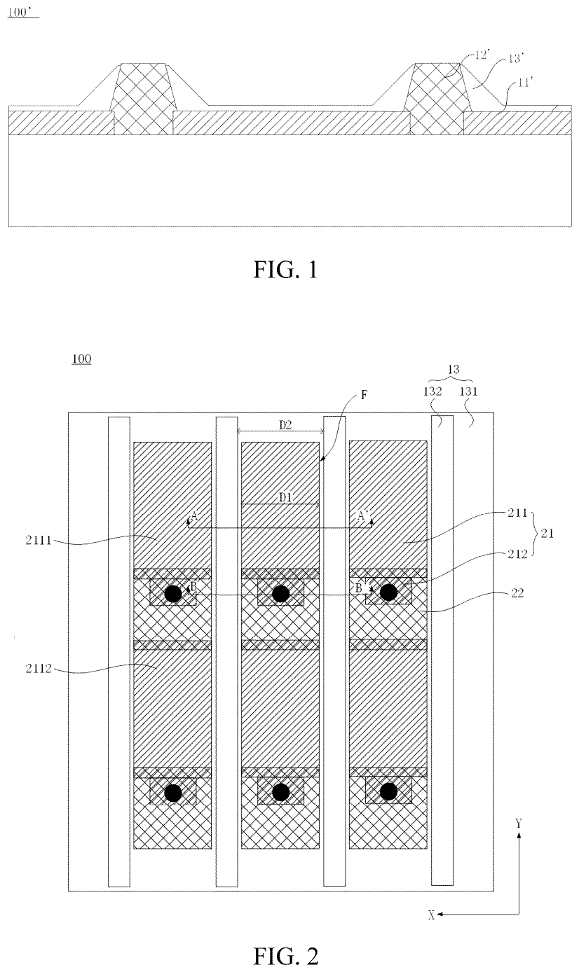

In the related art, as shown in FIG. 1, during the manufacturing process of an OLED display panel 100′, a pixel definition layer 12′ is generally formed on an array substrate with first electrodes 11′, the pixel definition layer 12′ has openings in one-to-one correspondence with light-emitting devices; then, ink is sprayed into the openings using an inkjet printing process, and the ink dries to form light-emitting function layers 13′. However, during the drying process, the ink tends to climb along sidewalls of the openings, and each of the formed light-emitting function layers 13′ is thick at the edges and thin in the middle of one opening. Moreover, since the first electrodes 11′ are fabricated before the pixel definition layer 12′, the pixel definition layer 12′ covers the edges of the first electrodes 11′, which leads to a more significant ink climb (i.e., the ink climbing along the sidewalls of the openings), thereby affecting the display effect of the OLED display panel.

In light of this, a display panel is provided in some embodiments of the present application. As shown in FIGS. 2 to 8, the display panel includes: a substrate 11, a planarization layer 13 located on the substrate 11, a plurality of first electrodes 21 located on the planarization layer 13 and arranged in an array, and a plurality of light-emitting function layers 23. The planarization layer 13 includes a planarization body 131 and a plurality of protrusions 132. Each of the protrusions 132 extends along a second direction Y, and the protrusions 132 are arranged side by side in a first direction X, where the first direction X and the second direction Y intersect each other. For example, the first direction X and the second direction Y may be perpendicular to each other.

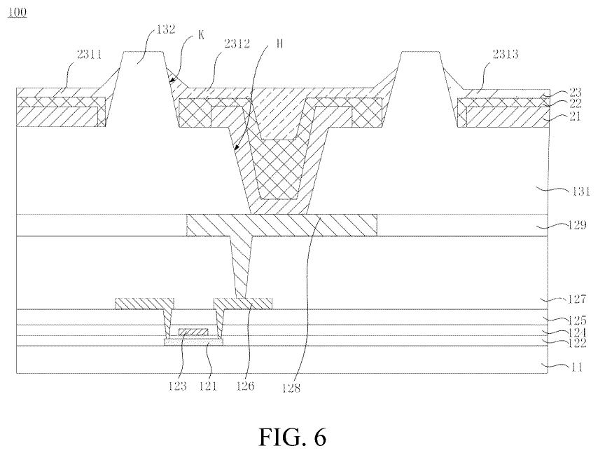

In some examples, as shown in FIGS. 5 and 6, the display panel further includes a driving circuit layer located between the substrate 11 and the planarization layer 13. Two adjacent protrusions 132 and the planarization body 131 together define a depression K, and the depression K has a plurality of via holes H that are spaced apart and penetrate through the planarization body 131. For example, the depression K located between two adjacent protrusions 132 extends along the second direction Y, and the plurality of via holes H in the depression K are spaced apart in the second direction Y. The plurality of first electrodes 21 may be in one-to-one correspondence with the plurality of via holes H. In this case, the first electrodes 21 are connected to the driving circuit layer through the via holes H.

For example, the planarization body 131 and the plurality of protrusions 132 may be integrally formed, so that the first electrodes 21 can be fabricated after the planarization layer 13, thereby effectively avoiding that the protrusions 132 cover the edges of the first electrodes 21 due to the protrusions 132 being fabricated after the first electrodes 21.

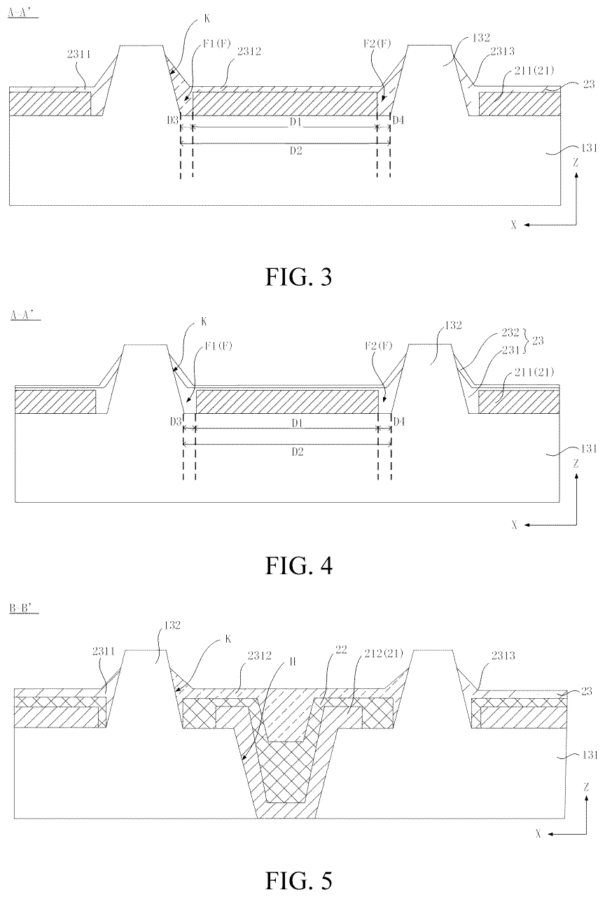

As shown in FIGS. 3 to 5, in the first direction X, the width of each protrusion 132 at the side away from the substrate 11 is less than the width of the protrusion 132 at the side close to the substrate 11. In this case, the cross section of the protrusion 132 is trapezoidal, and the cross section is parallel to both the first direction X and a third direction Z, where the third direction Z is a thickness direction of the substrate 11, and the third direction Z is perpendicular to both the first direction X and the second direction Y.

In some examples, the planarization layer 13 may be fabricated using a halftone mask, thereby forming the protrusions 132 and the via holes H in the planarization layer 13 simultaneously.

As shown in FIGS. 3 to 6, each of the light-emitting function layers 23 covers a corresponding one of the first electrodes 21. Each of the first electrodes 21 and one light-emitting function layer 23 together correspond to a single light-emitting device, and the light-emitting device further includes a second electrode, and the second electrode is disposed on a side of the light-emitting function layer 23 away from the corresponding first electrode 21. The driving circuit layer 12 can provide an anode signal to the first electrode 21, and the second electrode can receive a cathode signal. Under the action of both the cathode signal received at the second electrode and the anode signal received at the first electrode 21, the light-emitting function layer 23 can emit light, thereby achieving the display function of the display panel 100.

As shown in FIGS. 2 to 4, in the first direction X, each of the first electrodes 21 is located between two adjacent protrusions 132 and spaced from at least one of the two adjacent protrusions 132 by a gap F. The gap F is filled with a part of one of the light-emitting function layers 23.

With this arrangement, the gap F exist between the first electrode 21 and at least one of protrusion 132 adjacent to the first electrode 21, which allows the ink used to form the light-emitting function layer 23 to fill the gap F between the first electrode 21 and the at least one protrusion 132 during the process of fabricating the light-emitting function layers 23. In this way, part of the ink that would otherwise climb along the protrusions 132 is kept in the gap F between the first electrode 21 and the at least one protrusion 132, which effectively alleviates the ink climb, thereby helping improve the display effect of the display panel 100. In addition, since the part of the ink is kept in the gap F between the first electrode 21 and the at least one protrusion 132, the climb height of the ink is reduced, which can not only effectively prevent the ink from overflowing the depression K where the gap is located to cause color mixing with other light-emitting devices, but also help make the surface of the light-emitting function layer 23 away from the substrate 11 relatively flat, thereby increasing the effective light-emitting area of the light-emitting function layer 23 and improving the aperture ratio of the display panel 100. Moreover, since the part of the ink is kept in the gap F between the first electrode 21 and the at least one protrusion 132, the edges of the first electrode 21 may be effectively covered, thereby preventing short circuits between the first electrode 21 and the corresponding second electrode located on the light-emitting function layer 23.

In some embodiments, the gap F has a dimension less than or equal to 1 μm in the first direction X.

Since the light-emitting area of the light-emitting device is related to areas of the first electrode 21 and the flat portion of the light-emitting function layer 23. The existence of the gap F reduces the climb height of the ink used to form the light-emitting function layer 23, which may increase the area of the flat portion (excluding the climb portion) of the light-emitting function layer 23. However, an increase in the gap F will lead to a reduction in the area of the first electrode 21, resulting a reduction in the light-emitting area of the light-emitting device. The dimension of the gap F is greater than 0 and less than or equal to 1 μm, which may effectively reduce the ink climb height while ensuring that the light-emitting device has a relatively large light-emitting area, thereby improving the aperture ratio of the display panel.

It is worth noting that, since the cross section of the protrusion 132 is trapezoidal, the dimension of the gap F in the first direction X refers to the distance between the bottom of the protrusion 132 and the bottom of the first electrode 21 adjacent to the protrusion 132 in the first direction X.

In some embodiments, as shown in FIGS. 2 to 4, in the first direction X, a spacing D2 between two adjacent protrusions 132 is greater than the dimension of the first electrode 21 located between these two adjacent protrusions 132, which ensures that the gap F exists between the first electrode 21 and at least one protrusion 132 adjacent to the first electrode 21.

Since the cross section of the protrusion 132 is trapezoidal, the spacing between two adjacent protrusions 132 in the first direction X can refer to the spacing between two sides of the protrusions 132 close to the substrate 11 (i.e., the spacing between bottoms of the protrusions 132).

In some embodiments, as shown in FIGS. 2 to 4, the gap F exists between the first electrode 21 and each of two protrusions 132 adjacent to the first electrode 21.

As shown in FIGS. 3 and 4, the first electrode 21 located between two adjacent protrusions 132 is spaced from one of the protrusions 132 by a first gap F1 and spaced from the other one of the protrusions 132 by a second gap F2, which allows the first gap F1 and the second gap F2 to be filled with the ink used to form the light-emitting function layer 23, effectively alleviating the ink climb, and thereby helping improve the display effect of the display panel 100. Moreover, since part of the ink is kept in the first gap F1 and the second gap F2, the climb height of the ink can also be reduced, thereby effectively preventing the ink from overflowing the depressions K and causing color mixing with other light-emitting devices.

In some examples, in the first direction X, the dimension D3 of the first gap F1 is equal to the dimension D4 of the second gap F2. In this case, the first electrode 21 is located at the middle position between the two adjacent protrusions 132. After the light-emitting function layer 23 is fabricated, the thickness of the light-emitting function layer 23 at both ends in the first direction X is relatively consistent, which may ensure the uniformity of the light-emitting function layer 23, helping improve the light-emitting stability of the light-emitting device, and thereby improving the display effect of the display panel 100.

In other examples, in the first direction X, the dimension D3 of the first gap F1 and the dimension D4 of the second gap F2 may be unequal.

In some embodiments, as shown in FIG. 4, each of the light-emitting function layers 23 includes a hole injection layer 231 and a light-emitting layer 232 that are sequentially arranged in a direction away from the substrate 11, and the hole injection layer 231 is covered by the light-emitting layer 232. Each of the first electrodes 21 is covered by the hole injection layer 231 of a light-emitting function layer 23, and the gap F is filled with a part of the hole injection layer 231.

The hole injection layer 231 has a relatively low resistivity. Since the gap F exists between the first electrode 21 and the at least one protrusion 132 adjacent to the first electrode 21, the ink used to form the hole injection layer 231 will fill the gap F between the first electrode 21 and the at least one protrusion 132 during the process of fabricating the hole injection layers 231. As a result, the climb height of the hole injection layer 231 is reduced, which is beneficial for the light-emitting layer 232 covering the hole injection layer 231, thereby avoiding the formation of a leakage path between the first electrode 21 and the second electrode due to ineffective coverage of the hole injection layer 231 by the light-emitting layer 232.

In some examples, the light-emitting function layer 23 further includes a hole transport layer located between the hole injection layer 231 and the light-emitting layer 232, the hole transport layer covers the hole injection layer 231, and the light-emitting layer 232 covers the hole transport layer.

In some examples, the light-emitting function layer 23 further includes at least one of an electron transport layer and an electron injection layer that are located between the light-emitting layer 232 and the second electrode. When the light-emitting function layer 23 includes both the electron transport layer and the electron injection layer, the electron injection layer is located on a side of the electron transport layer close to the second electrode.

In some examples, as shown in FIGS. 3, 5, and 6, the plurality of light-emitting function layers 23 may include a first light-emitting function layer 2311, a second light-emitting function layer 2312, and a third light-emitting function layer 2313 that are used to emit red light, green light, and blue light, respectively, thereby achieving color display of the display panel 100.

In some embodiments, each of the protrusions 132 has a hydrophobic surface. For example, each of the protrusions 132 has a surface provided with a hydrophobic material, which can further prevent color mixing with the light-emitting devices on two sides of each of the protrusions 132.

In some examples, the surfaces of the protrusions 132 contain fluorine elements. The aggregation of fluorine elements can provide the surfaces of the protrusions 132 with good hydrophobicity, thus avoiding the arrangement of an additional hydrophobic material layer, which would lead to thickness increasement and cost increasement.

During the fabrication of the planarization layer 13, an initial planarization layer may be provided on the driving circuit layer, and materials containing fluorine elements are applied to the surface of the initial planarization layer away from the driving circuit layer; then, a pre-bake process is used such that fluorine elements aggregate in the surface of the initial planarization layer away from the driving circuit layer; next, a halftone mask process is used to form the protrusions 132 and via holes H, where the surfaces of the protrusions 132 away from the driving circuit layer becomes hydrophobic due to the aggregation of the fluorine elements.

In some embodiments, as shown in FIGS. 2, 5, and 6, each of the first electrodes 21 includes a body part 211 and a connecting part 212 located on a side of the body part 211. The body part 211 is disposed on the planarization layer 13 (e.g., the planarization body 131), and the connecting part 212 is partially located in one of the via holes H and electrically connected to the driving circuit layer. The body part 211 can achieve electrical connection with the driving circuit layer through the connecting part 212 which is partially located in the via hole H, thereby transporting the signal to the first electrode.

The display panel 100 further includes a plurality of planarization portions 22 that are in one-to-one correspondence with the plurality of first electrodes 21, each of the planarization portions 22 covers at least the connecting part 212 of a corresponding one of the first electrodes 21.

Each of the planarization portions 22 covers the connecting part 212 of a corresponding first electrode 21, which may effectively planarize the via holes H, avoiding depressions exist at the position of the via holes H that would require excessive ink (used to form the light-emitting function layers 23), thereby saving ink usage.

In some examples, as shown in FIG. 2, each of the planarization portions 22 covers the connecting part 212 of the corresponding first electrode 21 and an edge, close to the connecting part 212, of the body part 211 of a first electrode 21 adjacent to the corresponding first electrode 21, where the first electrode 21 adjacent to the corresponding first electrode 21 is located at a side of the connecting part 212 away from the body part 211 of the first electrode 21 to which the planarization portion 22 corresponds.

For example, two adjacent first electrodes 21 in the second direction Y are a first first electrode 2111 and a second first electrode 2112. One of the planarization portions 22 corresponding to the first first electrode 2111 covers the connecting part 212 (distinguished as the first connecting part later for clarity) of the first first electrode 2111 and an edge of the second first electrode 2112 close to the connecting part 212 (i.e., the first connecting part), and the connecting part 212 (i.e., the first connecting part) is located at a side of the body part 211 of the first first electrode 2111 close to the second first electrode 2112.

It is worth noting that, steps will be formed between the edges of the first electrodes 21 and the planarization layer 13 under the first electrodes 21 after the first electrodes 21 are formed. The existence of the steps will cause the thickness of the light-emitting function layers 23 to be relatively small at the steps during the drying process of ink for forming the light-emitting function layers 23, which will further lead to short-circuiting issues between the second electrodes and the first electrodes 21 at the steps after the second electrodes are fabricated.

Therefore, with the above arrangement, the planarization portion 22 can planarize the step formed between the corresponding first electrode 21 and the planarization layer 13, which is conducive to ensuring the uniform thickness of the light-emitting function layer 23 located at the position corresponding to the planarization portion, avoiding the need of additional materials for forming the light-emitting function layer 23, which would increase material costs. In addition, after the planarization portion 22 planarizes the step formed between the corresponding first electrode 21 and the planarization layer 13, the flatness at the position is also beneficial for the subsequent arrangement of the corresponding second electrode. Moreover, the planarization portion 22 can also cover the edge of the first electrode 21, which effectively isolate the first electrode 21 from the corresponding second electrode, thereby avoiding short-circuiting issues between the first electrode 21 and the corresponding second electrode.

In some examples, as shown in FIG. 2, in the first direction X, the dimension of the body part 211 is greater than the dimension of the connecting part 212, which may reduce the arrangement area of the first electrode 21. In this case, the planarization portion 22 can also cover edges of the body part 211 of the corresponding first electrode 21 close to the connecting part 212, which may further ensure that the short-circuiting issues will not happen between the first electrode 21 and the second electrode fabricated subsequently that are correspond to the planarization portion 22.

In other examples, in the first direction X, the dimension of the body part 211 may also be equal to the dimension of the connecting part 212, which is not limited in the present application.

In some embodiments, every two adjacent light-emitting function layers 23 in the second direction Y are connected with each other. That is, multiple first electrodes 21 are provided in the depression K between two adjacent protrusions 132, and the multiple light-emitting function layers 23 above the multiple first electrodes 21 are connected in sequence.

With this arrangement, the ink used to form the light-emitting function layers 23, after entered into the depressions K by inkjet printing, only climbs along the protrusions 132 at two sides of each of the depressions K, and there will be no ink climb between two adjacent first electrodes 21. In this way, the uniformity of the thickness of the light-emitting function layers 23 can be improved, thereby improving the display effect of the display panel 100.

In the first direction X, light-emitting function layers 23 may include the first light-emitting function layer 2311, the second light-emitting function layer 2312, and the third light-emitting function layer 2313, thereby achieving the color display of the display panel 100.

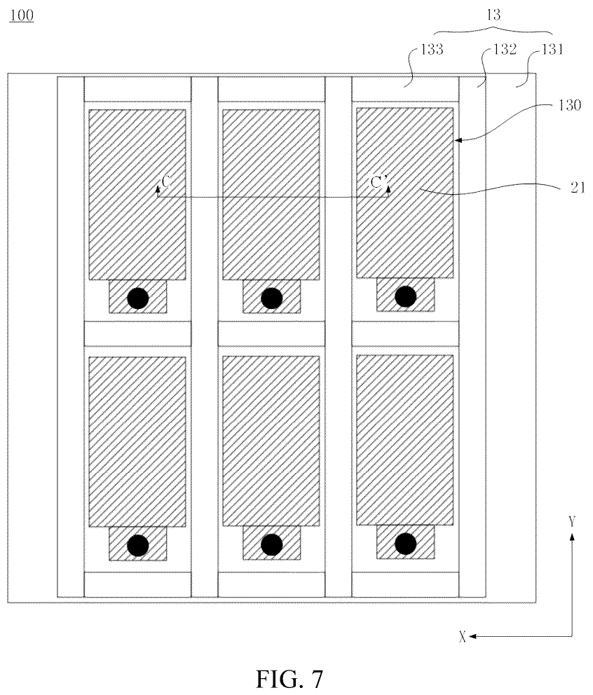

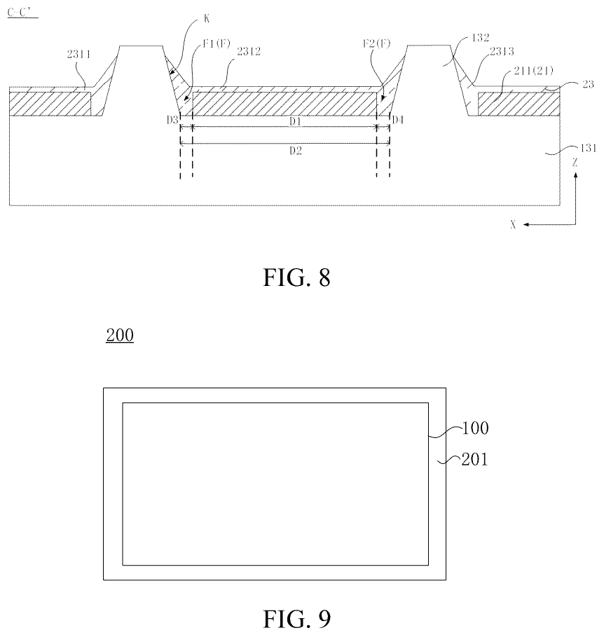

In some embodiments, as shown in FIGS. 7 and 8, the planarization layer 13 further includes a plurality of limiting portions 133 that are arranged in an array on a side of the planarization body 131 away from the substrate 11. Each of every two adjacent limiting portions 133 in the second direction Y is connected with two protrusions 132 located respectively on two sides of the each of every two adjacent limiting portions 133 to define a light-emitting device area 130, where one first electrode 21 and a light-emitting function layer 23 covering the one first electrode 21 are disposed.

With this arrangement, multiple light-emitting device areas 130 may be defined by arranging the plurality of limiting portions 133 and arranging each limiting portion 133 connected to adjacent two protrusions 132. Each light-emitting device area 130 may be used to arrange a corresponding light-emitting device, which may increase the number of light-emitting devices that can be independently controlled, thereby improving the resolution of the display panel 100.

In some embodiments, as shown in FIGS. 7 and 8, each of the first electrodes 21 is spaced apart from at least one limiting portion 133 adjacent to the first electrode 21. In this case, spacing(s) can be formed between the first electrode 21 and the at least one limiting portion 133 adjacent to the first electrode 21, and the ink used to form the light-emitting function layer 23 will fill the spacing(s) between the first electrode 21 and the at least one limiting portion 133. In this way, part of the ink that would otherwise climb along the limiting portions 133 is kept in the gap between the first electrode 21 and the at least one limiting portion 133, which effectively alleviates the ink climb, thereby helping improve the display effect of the display panel 100. Moreover, since the part of the ink is kept in the spacing(s) between the first electrode 21 and the limiting portion 133, the climb height of the ink can also be reduced, thereby effectively preventing the ink from overflowing the corresponding light-emitting device area 130 and causing color mixing with other light-emitting devices.

In some examples, spacings exist between the first electrode 21 and two limiting portions 133 adjacent to the first electrode 21, which can further effectively alleviate the ink climb and prevent the color mixing with other light-emitting devices due to the ink overflows the light-emitting device area 130, thereby improving the display effect of the display panel 100.

In some embodiments, as shown in FIGS. 7 and 8, all of the limiting portions 133 and the protrusions 132 are integrally formed, which may allow the planarization layer 13 to be fabricated in one process, thereby improving the manufacturing efficiency of the planarization layer 13.

In some examples, each of the limiting portions 133 has a hydrophobic surface. For example, each of the limiting portions 133 has a surface provided with a hydrophobic material, which can further prevent color mixing with the light-emitting devices on either side of each of the limiting portions 133.

For example, the surfaces of the limiting portions 133 can contain fluorine elements.

In some embodiments, the driving circuit layer 12 includes a plurality of pixel driving circuits, each of which may be electrically connected to a corresponding first electrode 21, so that each pixel driving circuit can control the corresponding light-emitting device to emit light, thereby achieving the display function of the display panel 100.

In some examples, the pixel driving circuit may be directly electrically connected to the first electrode 21. Alternatively, the pixel driving circuit may be electrically connected to the first electrode 21 through a connecting member, which is not limited in the present application.

In some embodiments, as shown in FIG. 6, the pixel driving circuit includes a plurality of thin-film transistors and at least one storage capacitor, the thin-film transistors each include an active layer, a gate, a source, and a drain that are disposed above the substrate 11. The layer where the active layer is located is the semiconductor layer 121; the layer where the gate is located is the gate metal layer 123; and the layer where the source and the drain are located is the source-drain metal layer 126.

A gate insulation layer 122 is provided between the semiconductor layer 121 and the gate metal layer 123. Interlayer insulation layer(s) are provided between the gate metal layer 123 and the source-drain metal layer 126. For example, the interlayer insulation layer(s) may include a first interlayer insulation layer 124 and a second interlayer insulation layer 125 disposed in sequence. In this case, a metal layer may be provided between the first interlayer insulation layer 124 and the second interlayer insulation layer 125 such that an electrode of the storage capacitor or other circuit devices are arranged in the metal layer. A passivation layer 127 may be also provided on a side of the source-drain metal layer 126 away from the substrate 11.

One of the source and the drain of the thin-film transistor is electrically connected to the first electrode 21 of one light-emitting device to transmit the anode signal to the first electrode 1, thereby driving the light-emitting device to emit light. The source or the drain of the thin-film transistor may be directly or indirectly electrically connected to the first electrode 21 of the light-emitting device.

In some examples, a connecting electrode layer 128 is also provided on the passivation layer 127, a connecting electrode in the connecting electrode layer 128 is electrically connected to the source or the drain of the thin-film transistor through a via hole located in the passivation layer 127, and the connecting electrode is further electrically connected to the first electrode 21 of the light-emitting device through the via hole H, thereby achieving the transmission of the anode signal.

In some examples, an insulation layer 129 is also provided on a side of the connecting electrode layer 128 away from the substrate 11, and the insulation layer 129 exposes the connecting electrode in the connecting electrode layer 128 to achieve electrical connection between the connecting electrode and the first electrode 21. As an implementation, the insulation layer 129 and the planarization layer 13 may be fabricated simultaneously.

It will be noted that the gate metal layer 123 may be located on either the side of the semiconductor layer 121 away from or close to the substrate 11. In the case where the gate metal layer 123 is located on the side of the semiconductor layer 121 away from the substrate 11, the gate of the thin-film transistor in the pixel driving circuit is on the side of the active layer away from the substrate 11, and thus the thin-film transistor has a top-gate structure. In the case where the gate metal layer 123 is located on the side of the semiconductor layer 121 close to the substrate 11, the gate of the thin-film transistor in the pixel driving circuit is on the side of the active layer close to the substrate 11, and thus the thin-film transistor has a bottom-gate structure.

A display apparatus is provided in some embodiments of the present application, as shown in FIG. 9, the display apparatus 200 includes the display panel 100 described in any one of the above embodiments.

Since including the display panel 100, the display apparatus 200 has all the technical effects of the display panel 100 mentioned above, which will not be repeated here.

In some examples, the display apparatus 200 further includes a frame 201 for fixing the display panel 100.

In some examples, the display apparatus 200 may be any component with display functions, such as a watch, tablet computer, laptop computer, monitor, television, billboard, digital photo frame, printer with display function, telephone, mobile phone, personal digital assistant (PDA), digital camera, portable video camera, viewfinder, navigator, household appliance, information inquiry device (such as business inquiry devices in departments of electronic government affairs, banks, hospitals, electricity and post offices), or the like.

Some embodiments of the present application have been described in detail above. The description of the above embodiments merely aims to help to understand the present application. Many modifications or equivalent substitutions with respect to the embodiments may occur to those of ordinary skill in the art based on the present application. Thus, these modifications or equivalent substitutions shall fall within the scope of the present application.

What is claimed is:

1. A display panel comprising:
a substrate;
a planarization layer disposed on the substrate, the planarization layer comprising a planarization body and a plurality of protrusions arranged side by side in a first direction on a side of the planarization body away from the substrate, each of the protrusions extending along a second direction;
a plurality of first electrodes arranged in an array on the planarization body, wherein in the first direction each of the first electrodes is located between two adjacent ones of the protrusions and spaced from at least one of the two adjacent ones of the protrusions by a gap; and
a plurality of light-emitting function layers respectively covering the first electrodes, wherein the gap is filled with a part of one of the light-emitting function layers covering the each of the first electrodes.

2. The display panel according to claim 1, wherein the gap has a dimension less than or equal to 1 μm in the first direction.

3. The display panel according to claim 1, wherein the each of the first electrodes is spaced from each of the two adjacent ones of the protrusions by the gap.

4. The display panel according to claim 1, wherein each of the light-emitting function layers comprises a hole injection layer and a light-emitting layer that are sequentially arranged in a direction away from the substrate, and the hole injection layer is covered by the light-emitting layer; and
the each of the first electrodes is covered by the hole injection layer of the one of the light-emitting function layers, and the gap is filled with a part of the hole injection layer of the one of the light-emitting function layers.

5. The display panel according to claim 1, wherein each of the protrusions has a surface provided with a hydrophobic material.

6. The display panel according to claim 1, further comprising:
a driving circuit layer disposed on the substrate; and
a plurality of planarization portions respectively corresponding to the plurality of first electrodes;
wherein the planarization layer is disposed on the driving circuit layer and provided with a plurality of via holes;
the each of the first electrodes comprises a body part disposed on the planarization body and a connecting part located on a side of the body part, and the connecting part is partially located in one of the via holes and electrically connected to the driving circuit layer; and
each of the planarization portions covers at least the connecting part of one of the first electrodes corresponding to the each of the planarization portions.

7. The display panel according to claim 6, wherein every two adjacent ones of the first electrodes in the second direction comprise a first first electrode and a second first electrode;
one of the planarization portions corresponding to the first first electrode covers the connecting part of the first first electrode and an edge of the second first electrode close to the connecting part of the first first electrode; and
the connecting part of the first first electrode is located on a side of the body part of the first first electrode close to the second first electrode.

8. The display panel according to claim 6, wherein every two adjacent ones of the light-emitting function layers in the second direction are connected with each other.

9. The display panel according to claim 1, wherein the planarization layer further comprises a plurality of limiting portions arranged in an array on a side of the planarization body away from the substrate; and
each of every two adjacent ones of the limiting portions in the second direction is connected with two of the protrusions located respectively on two sides of the each of every two adjacent ones of the limiting portions to define a light-emitting device area where one of the first electrodes and one of the light-emitting function layers covering the one of the first electrodes are disposed.

10. The display panel according to claim 9, wherein the planarization body, the limiting portions and the protrusions are integrally formed; and
each of a surface of each of the limiting portions away from the substrate and a surface of each of the protrusions away from the substrate is provided with a hydrophobic material.

11. The display panel according to claim 9, wherein the each of the first electrodes is spaced apart from at least one of the limiting portions adjacent to the each of the first electrodes.

12. A display apparatus comprising a display panel, wherein the display panel comprises:
a substrate;
a planarization layer disposed on the substrate, the planarization layer comprising a planarization body and a plurality of protrusions arranged side by side in a first direction on a side of the planarization body away from the substrate, each of the protrusions extending along a second direction;
a plurality of first electrodes arranged in an array on the planarization body, wherein in the first direction each of the first electrodes is located between two adjacent ones of the protrusions and spaced from at least one of the two adjacent ones of the protrusions by a gap; and
a plurality of light-emitting function layers respectively covering the first electrodes, wherein the gap is filled with a part of one of the light-emitting function layers covering the each of the first electrodes.

13. The display apparatus according to claim 12, wherein the gap has a dimension less than or equal to 1 μm in the first direction.

14. The display apparatus according to claim 12, wherein the each of the first electrodes is spaced from each of the two adjacent ones of the protrusions by the gap.

15. The display apparatus according to claim 12, wherein each of the light-emitting function layers comprises a hole injection layer and a light-emitting layer that are sequentially arranged in a direction away from the substrate, and the hole injection layer is covered by the light-emitting layer; and
the each of the first electrodes is covered by the hole injection layer of the one of the light-emitting function layers and the gap is filled with a part of the hole injection layer of the one of the light-emitting function layers.

16. The display apparatus according to claim 12, wherein each of the protrusions has a surface provided with a hydrophobic material.

17. The display apparatus according to claim 12, wherein the display panel further comprises a driving circuit layer disposed on the substrate and a plurality of planarization portions respectively corresponding to the plurality of first electrodes;
the planarization layer is disposed on the driving circuit layer and provided with a plurality of via holes;
the each of the first electrodes comprises a body part disposed on the planarization body and a connecting part located on a side of the body part, and the connecting part is partially located in one of the via holes and electrically connected to the driving circuit layer; and
each of the planarization portions covers at least the connecting part of one of the first electrodes corresponding to the each of the planarization portions.

18. The display apparatus according to claim 17, wherein every two adjacent ones of the first electrodes in the second direction comprise a first first electrode and a second first electrode;
one of the planarization portions corresponding to the first first electrode covers the connecting part of the first first electrode and an edge of the second first electrode close to the connecting part of the first first electrode; and
the connecting part of the first first electrode is located on a side of the body part of the first first electrode close to the second first electrode.

19. The display apparatus according to claim 12, wherein the planarization layer further comprises a plurality of limiting portions arranged in an array on a side of the planarization body away from the substrate; and
each of every two adjacent ones of the limiting portions in the second direction is connected with two of the protrusions located respectively on two sides of the each of every two adjacent ones of the limiting portions to define a light-emitting device area where one of the first electrodes and one of the light-emitting function layers covering the one of the first electrodes are disposed.

20. The display apparatus according to claim 19, wherein the planarization body, the limiting portions and the protrusions are integrally formed; and
each of a surface of each of the limiting portions away from the substrate and a surface of each of the protrusions away from the substrate is provided with a hydrophobic material.
